(19) United States
(12) Patent Application Publication
(10) Pub. No.: US 2026/0150282 A1
(43) Pub. Date: May 28, 2026

(54) Ga2O3 BASED NONVOLATILE FLASH MEMORY FOR OXIDE ELECTRONICS AND METHOD

(71) Applicant: KING ABDULLAH UNIVERSITY OF SCIENCE AND TECHNOLOGY, Thuwal (SA)

(72) Inventors: Vishal KHANDELWAL, Thuwal (SA); Xiaohang LI, Thuwal (SA)

(21) Appl. No.: 19/121,579

(22) PCT Filed: Oct. 19, 2023
(86) PCT No.: PCT/IB2023/060584

§ 371 Date: Apr. 16, 2025

Related U.S. Application Data
(60) Provisional application No. 63/417,761, filed on Oct. 20, 2022.

(51) Int. Cl. H10B 41/30

(52) U.S. Cl. CPC H10B 41/30

(57) ABSTRACT

A nonvolatile flash memory cell includes a source electrode, a drain electrode, and a gate column. The drain electrode is cylindrical, the gate column is tubular and surrounds the drain electrode, and the source electrode surrounds the gate column.

### CROSS-REFERENCE TO RELATED APPLICATIONS

This application claims priority to U.S. Provisional Patent Application No. 63/417,761, filed on Oct. 20, 2022, entitled “DEMONSTRATION OF ULTRAWIDE BANDGAP β-Ga2O3 NONVOLATILE FLASH MEMORY,” the disclosure of which is incorporated herein by reference in its entirety.

### BACKGROUND OF THE INVENTION

### Technical Field

Embodiments of the subject matter disclosed herein generally relate to a nonvolatile flash memory that is based on oxide electronics and method for making such a memory, and more particularly, to a β-Ga₂O₃ memory cell for a nonvolatile flash memory.

### Discussion of the Background

(Ultra)wide bandgap oxides have remarkable application potential in transparent and flexible electronics, high power and radio frequency (RF) electronics, ultra-violet (UV) photonics, and extreme environment electronics. To date, several oxide semiconductors such as indium gallium zinc oxide (InGaZnO), In₂O₃, and β-Ga2O3 [1] have been widely explored in numerous applications including solid-state displays, thin-film transistors, power devices, and UV photodetectors. Note that “oxide electronics” is understood herein as referring to a field of research and technology that explores the use of oxide materials, specifically transition metal oxides, for various electronic applications. These oxide materials exhibit unique and promising electronic properties that make them attractive for use in electronic devices. Some key features and applications of oxide electronics include: high electron mobility, insulating and semiconducting properties, transparent conductors for some oxide materials, high-temperature stability, etc. However, Si is not typically considered an oxide material in the context of oxide electronics because Si is a semiconducting element, not an oxide compound. Oxide electronics and silicon-based electronics are separate fields, each with its own set of materials, devices, and applications. Oxide electronics focuses on leveraging the unique electronic properties of oxide compounds, whereas silicon-based electronics relies on the properties of silicon as a semiconductor.

Among the oxide materials, ultrawide bandgap β-Ga₂O₃ (E_{G}˜4.9 eV) has emerged as a promising candidate, especially for realizing oxide electronics, due to its superior properties including high-quality epitaxial films, wide n-type doping range from semi-insulating to highly conducting films, high chemical, and thermal stability. Note that gallium oxide exists in several crystallographic phases, with the most common being alpha-gallium oxide (α-Ga₂O₃) and beta-gallium oxide (β-Ga₂O₃). α-Ga₂O₃ has a monoclinic crystal structure, while β-Ga₂O₃ has a hexagonal crystal structure. β-Ga₂O₃ is the most stable phase at room temperature.

So far, β-Ga₂O₃-based power transistors [2], Schottky diodes [3], and solar-blind photodetectors [4] have been extensively studied. In this respect, FIG. 1 shows a power transistor 100 having a Fe-dopped Ga₂O₃ substrate 102, an n-Ga₂O₃ channel layer 104 and a SiO₂ layer 106 and FIG. 2 shows a Schottky Diode 200 having a Ga₂O₃ substrate 202 and an epitaxial Ga₂O₃ layer 204 forming an n-type layer. P-type layers 206 made of NiOₓ are located over the epitaxial Ga₂O₃ layer 204 to form a pn junction. Neither of these devices is a pure oxide electronics (because of the presence of SiO₂ layers) and none of them are appropriate for a nonvolatile flash memory.

For memory devices, β-Ga₂O₃-based resistive random-access memory (RRAM) has been investigated [5, 6]. However, the filamentary behavior of β-Ga₂O₃ RRAMs and their precise control remains unclear. Moreover, β-Ga₂O₃ RRAMs will require integration with an appropriate selector device [7, 8] requiring a considerate effort for achieving commercial maturity. Meanwhile, flash memory devices are a highly scalable alternative that exhibits substantial maturity due to decades of device exploration. Furthermore, trapping of electrons in the floating gate (FG) is a promising approach to realize enhancement-mode (E-mode) operation to get normally-OFF transistor operation.

The development of β-Ga₂O₃-based flash memory devices is deemed to play a pivotal role in realizing future oxide electronics for various application fields. However, Ga₂O₃ is not commonly used in non-volatile flash memory for several reasons. Ga₂O₃ is primarily known for its properties as a wide-bandgap semiconductor material. While it has potential applications in power electronics and high-temperature environments, it lacks the specific properties required for non-volatile memory storage. Non-volatile memory technologies like NAND and NOR flash rely on the ability to trap and release electrons in a controlled manner, which is not a characteristic of Ga₂O₃.

In addition, non-volatile flash memory technologies like NAND and NOR flash have been in development for decades and have achieved a high level of maturity and reliability. They are based on silicon-based materials and have undergone extensive optimization for mass production, making them cost-effective and widely adopted in various applications. Manufacturing Ga₂O₃-based memory technologies would require a significant departure from the established silicon-based fabrication processes. Compatibility with existing manufacturing infrastructure and processes is a significant factor in determining the feasibility and adoption of new memory technologies. Ga₂O₃ would require the development of entirely new manufacturing processes and equipment.

Thus, there is a need for a new nonvolatile flash memory that can take advantage of the wide gap of the Ga₂O₃, but would not encounter the problems of Si integration.

### SUMMARY OF THE INVENTION

According to an embodiment, there is a nonvolatile flash memory cell that includes a source electrode, a drain electrode, and a gate column. The drain electrode is cylindrical, the gate column is tubular and surrounds the drain electrode, and the source electrode surrounds the gate column.

According to another embodiment, there is a nonvolatile flash memory that includes plural nonvolatile flash memory cells, plural bit lines connected to source electrodes of the plural memory cells, and plural word lines connected to gate electrodes of the plural memory cells. A memory cell of the plural memory cells includes a source electrode, a drain electrode, and a gate column. The drain electrode is cylindrical, the gate column is tubular and surrounds the drain electrode, and the source electrode surrounds the gate column.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a power transistor that uses a Ga₂O₃ layer;

FIG. 2 is a schematic diagram of a Schottky diode that uses a Ga₂O₃ layer;

FIG. 3A is an overview of a memory cell having an ultrawide bandgap Ga₂O₃ film, FIG. 3B is a cross-section view of the memory cell of FIG. 3A, and FIG. 3C is a top view of the same memory cell;

FIG. 4 is a flow chart of a method for making the memory cell of FIGS. 3A to 3C;

FIG. 5A illustrates the program characteristics of the memory cell at room temperature, FIG. 5B illustrates the erase characteristics of the memory cell, and FIG. 5C illustrates the program and erase characteristics after the first cycle;

FIG. 6A illustrates the measured V_{TH} of the memory cell after the program and erase operations, and FIG. 6B illustrates the retention characteristics of the memory cell;

FIG. 7A illustrates the energy band profile along vertical outline through the gate column for isolated layers, FIG. 7B shows the same during a programming operation, and FIG. 7C shows the same during an erasing operation; and

FIG. 8 is a schematic of a nonvolatile flash memory using the memory cell shown in FIGS. 3A to 3C.

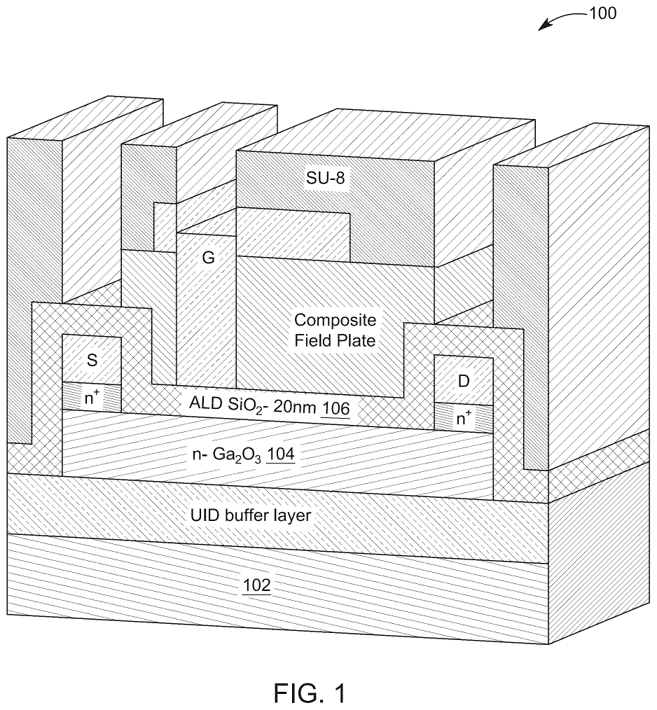

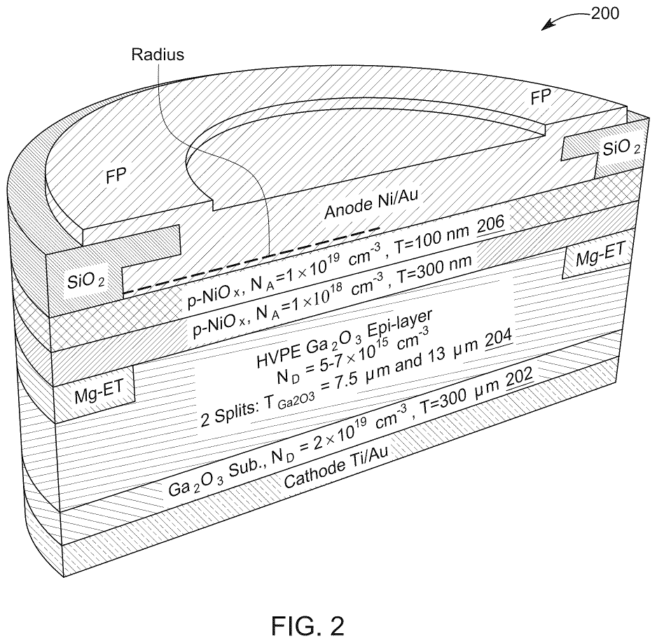

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a β-Ga₂O₃ film based nonvolatile flash memory cell. However, the embodiments to be discussed next are not limited to a memory cell, but may be applied to any memory or device that is based on oxide electronics.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel β-Ga₂O₃ film-based memory cell using TiN metal as the floating gate (FG) is introduced. The oxide-based memory cell exhibits a normally-ON behavior, whereas positive and negative voltage pulses were applied for programming and erasing operation, respectively. A large memory of larger than 4 V was obtained between the programming and erasing state with memory retention of >5000 s. A large program bias is shown to shift the threshold voltage (V_{TH}), thereby promoting the E-mode operation. The β-Ga₂O₃ flash memory cells reported in the following embodiments show a large nonvolatile memory window and a desirable memory retention characteristic.

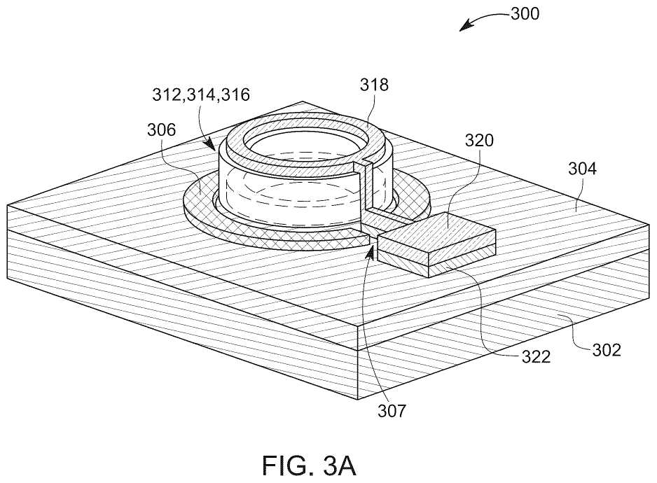

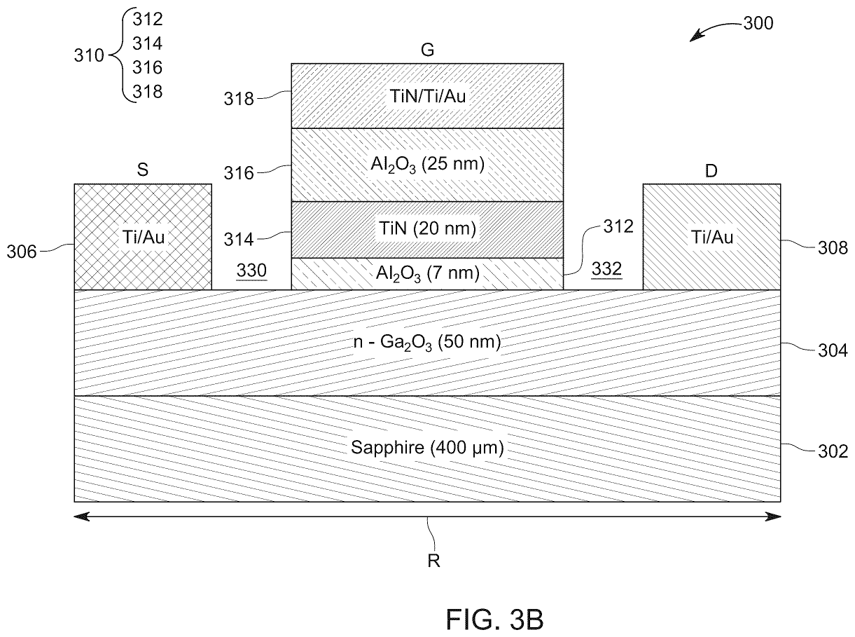

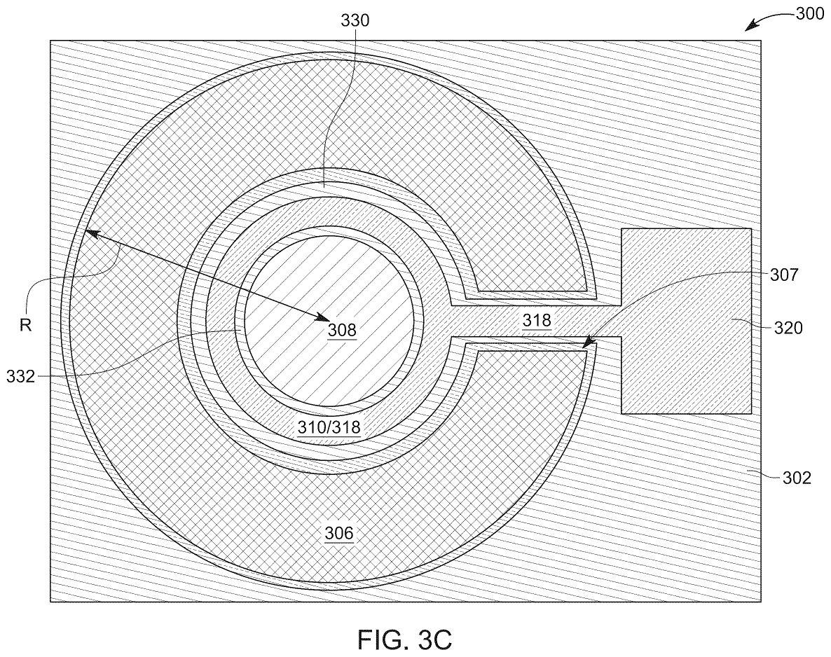

In one embodiment, as illustrated in FIGS. 3A to 3C, a flash memory cell 300 is made to include only oxide electronics, i.e., no silicon oxide-based layers (note that β-Ga₂O₃ film doped with Si atoms is not considered a silicon oxide-based layer). In this regard, although SiO₂ is an essential material in traditional silicon-based electronics, it is not typically considered an active material in the field of oxide electronics. Further, the figures show a novel circular geometry for the flash memory cell 300. The symmetric circular structure is selected to effectively trap and de-trap the electrons. In addition, the novel choice of the various layers and their thicknesses further enhance the trapping and de-trapping of the electrons, which makes this memory cell perform better than some of the existing Si-based memory cells.

More specifically, FIG. 3A shows an overview of the memory cell 300 while FIG. 3B shows a cross-section and FIG. 3C shows a top view of the memory cell. The figures show a substrate (for example, c-plane sapphire) 302 having a thickness of about 400 μm. An n-doped β-Ga₂O₃ film 304 is located over substrate 302. A Ti/Au source electrode S 306 and a Ti/Au drain electrode D 308 are located over the n-doped β-Ga₂O₃ film 304. In one embodiment, the source electrode, the drain electrode and a gate column 310 are directly located on the β-Ga₂O₃ film 304. As illustrated in FIG. 3C, the two electrodes are circular, with the drain electrode 308 encircled by the source electrode 306. Note that FIG. 3B is a cross-section of the memory cell 300 that extends only along the radius R of the memory cell, and not along the entire diameter of the cell.

The gate column G 310 is shown in more detail in FIG. 3B. It includes a thin Al₂O₃ tunneling oxide layer 312 located on the β-Ga₂O₃ film 304. In one application, the tunneling oxide layer 312 is formed directly on the β-Ga₂O₃ film 304. A floating gate FG 314 is located on the tunneling oxide layer 312. The FG 314 may be made of TiN. A thick Al₂O₃ blocking oxide layer 316 is located on the FG 314 and a control gate 318 is located over the blocking oxide layer 316. In one application, the Al₂O₃ material may be replaced with an oxide which has a higher conduction band offset (>1.5 eV) than Ga₂O₃.

As shown in FIG. 3C, the drain electrode 308 is shaped as a cylinder, the gate column 310 (and corresponding gate electrode 318) has a tubular shape, with the drain electrode 308 being fully enclosed by the gate column 310. The source electrode 306 also has a tubular shape, partially enclosing the gate column 310. The control gate 318 of the gate column 310 extends through an opening 307 of the source electrode 306, to a pad 320. The pad 320 is electrically insulated from the substrate 302, by an insulator pad 322, as shown in FIG. 3A. FIGS. 3B and 3C show openings 330 and 332, with opening 330 being located between the source electrode 306 and the gate column 310 and the opening 332 being located between the gate column 310 and the drain electrode 308.

The FG 314 configuration ensures that the memory cell 300 has good storage capabilities. In this embodiment, once a positive voltage is applied to the control gate 318, the electrons from the Ga₂O₃ semiconductor film 304 tunnel through the thin tunneling oxide layer 312 and resides in FG 314. Due to the large potential barrier at both sides of FG 314, the electrons cannot escape and are eventually trapped. This trapping of electrons is known as the programming operation of the memory. These electrons can only be released by applying a negative voltage at the control gate 318. When the negative voltage bias is applied to control gate 318, the stored electrons in FG 314 will tunnel back to the Ga₂O₃ semiconductor film 304 and be released. This de-trapping (releasing) of electrons is known as the erasing operation of the memory. Therefore, the FG architecture of FIGS. 3A to 3C can trap and release the electrons in a controlled manner for stable memory operation.

The architecture illustrated in FIGS. 3A to 3C includes a novel geometry and/or a novel choice of each layer to perform the stable memory operation. Regarding geometry, the memory cell has a circular geometry as illustrated in FIGS. 3A and 3C. The symmetric circular structure is employed to effectively trap and de-trap the electrons. The choice of different layers and their thickness also contributes to the memory cell operation. FG 314 was selected in this embodiment to be made of a metal, e.g., TiN. A reason for choosing TiN is to avoid the diffusion of FG metal to the tunneling and blocking oxides (Al₂O₃) layers 312 and 316 at high temperatures. Also, it provides a large potential well between the tunneling and blocking oxides so that electrons can be trapped for a long time, which eventually increases the retention time of the memory.

The tunneling oxide has been selected to be a thin layer of Al₂O₃, which provides efficient electron tunneling for electron trapping and de-trapping during programming and erasing operations. Also, it has a large dielectric constant with a high conduction band offset with Ga₂O₃, which induces the large accumulation and depletion of electrons for a large current ON-OFF ratio of FG transistor. These features and their impact on the functionality of the memory cell are discussed later.

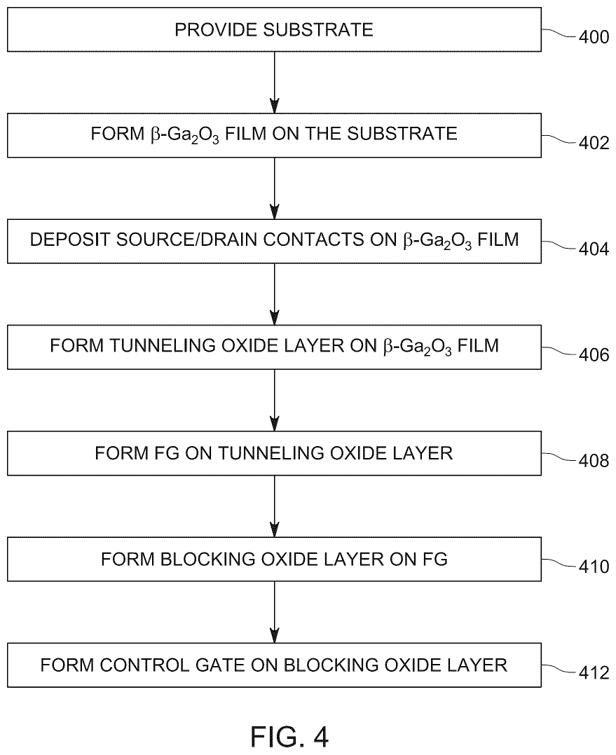

A method for making the memory cell 300 is discussed with regard to FIG. 4. In step 400, the sapphire substrate 302 was provided. In step 402, a 50 nm thick β-Ga₂O₃ film 304 was grown on a c-plane of the sapphire substrate 302. A pulsed laser deposition (PLD) system was employed to grow the heteroepitaxial film 304 using a Si-doped β-Ga₂O₃ target. The growth temperature was maintained at 700° C., whereas the laser ablation frequency and laser energy were set to 5 Hz and 100 mJ, respectively. The oxygen partial pressure was kept as 4 mTorr during growth. Post-growth, the samples were cleaned thoroughly using acid and acetone-IPA solvent treatment.

In step 404, circular Ti/Au (20/100 nm) source/drain (SD) ohmic contacts 306 and 308 were formed on the β-Ga₂O₃ film 304. The metals were deposited using a DC/RF sputtering system and patterned using the standard photo-lithography and lift-off process. Other methods are possible. The ohmic contacts were then annealed at 400° C. for 60 s in N₂ ambient. Thereafter, a 7 nm thick Al₂O₃ layer 312 serving as the tunneling oxide was deposited on film 304, in step 406, using an atomic layer deposition (ALD) system at 250° C. A 20 nm of TiN metal as the FG 314 was then deposited in step 408 on the tunneling oxide layer 312 followed by the conventional photo-lithography and lift-off process for patterning. Next, a 25 nm thick Al₂O₃ blocking oxide layer 316 was deposited in step 410 using ALD at 250° C. Finally, a TiN/Ti/Au (20/20/70 nm) control gate 318 was formed in step 412 using the sputtering and conventional photolithography process. TiN deposition was accomplished using a DC/RF sputtering system having a high-purity Ti target in the N₂ reactive chamber. Note that the control gate 318 extends on top of the blocking oxide layer 316 and also on the side of the other layers/films forming the gate column 310, as shown in FIG. 3A. One skilled in the art would understand that an insulator material may be formed on the side of the gate column 310 prior to depositing the control gate 318 to prevent electrical contact between the control gate 318 and other layers of the gate column 310. The Al₂O₃ di-electric layer present on top of the SD ohmic contacts was removed to expose them, via BCl₃-based dry etching. The diameter of the drain contact 308 was kept at about 200 μm in this embodiment. A doughnut-shape control gate 318 had an inner circle and outer circle diameter of about 220 and 280 μm, respectively, indicating the effective gate length to be 30 μm. FG 314 also had a doughnut-shape geometry (inner circle and outer circle diameter of 240 and 260 μm, respectively) and was kept within the boundaries of the control gate. The control gate-to-drain and control gate-to-source distances 332 and 330, were kept at about 10 μm and 20 μm, respectively. Other values may be used. Those skilled in the art wound understand that all the specific numbers presented herein may be varied to be about plus or minus 20% of their listed values. Also, the metals mentioned herein may be replaced with similar metals. The oxide materials discussed herein may also be replaced with similar oxides as understood in the oxide electronics field.

The quality of the epitaxial film 304 was characterized using X-ray diffraction (XRD) and an atomic force microscope (AFM). The free carrier concentration inside the β-Ga₂O₃ film was measured using a Hall-effect measurement system. The XRD pattern (not shown) of the β-Ga₂O₃ film 304 exhibited (−201), (−402), and (−603) peaks, which confirm the mono-orientation of β-Ga₂O₃ film on the sapphire substrate 302. The RMS roughness of the film 304 was observed to be ˜0.8 nm, indicating a smooth surface morphology. Based on the Hall-effect measurements, the electron concentration and mobility of the β-Ga₂O₃ film 304 were found to be about 5×10¹⁸ cm⁻³ and about 0.35 cm⁻² V⁻¹ s⁻¹ at room temperature (RT).

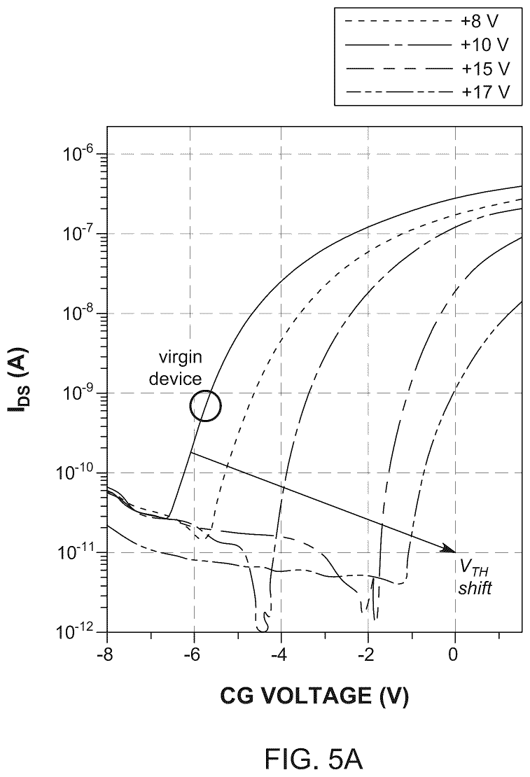

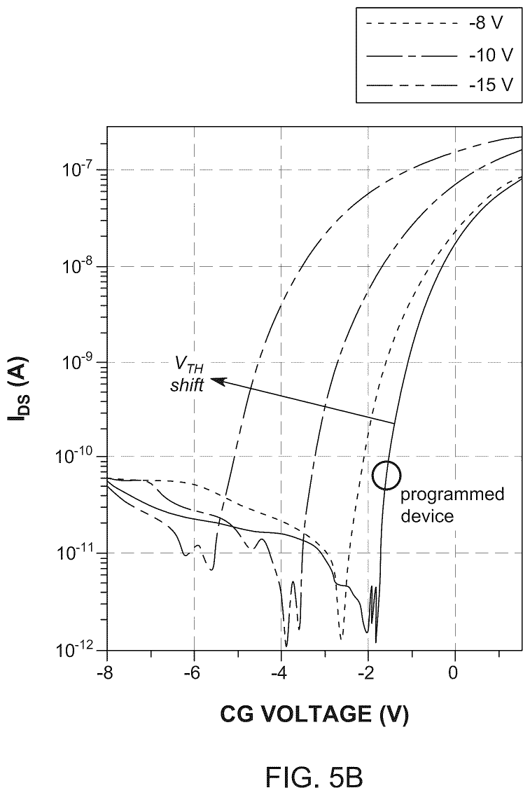

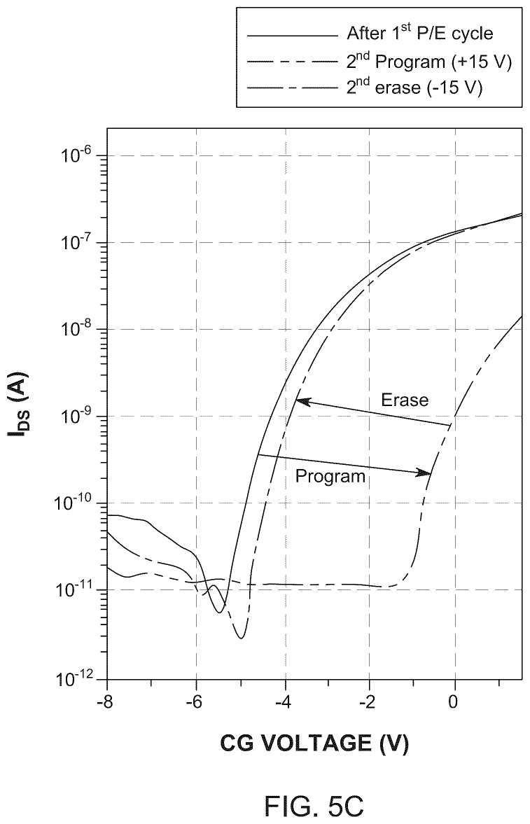

Next, the β-Ga₂O₃ flash memory cell 300 was characterized to validate the nonvolatile memory operation. FIG. 5A shows the transfer characteristics of the β-Ga₂O₃ flash memory cell 300 at V_{DS}=1 V post application of program voltage pulses. The value of V_{TH} was estimated from the transfer characteristics using the extrapolation in the linear region method. The virgin device showed a normally-ON behavior with a V_{TH} of −4.5 V. Subsequently, the application of different positive voltage pulses to the control gate 318 resulted in a positive V_{TH} shift, validating the programming operation of the memory, as shown in the figure. For instance, a +17 V, 100 ms pulse applied to the control gate 318 yields a V_{TH} of 0.3 V. Note that such a positive value of V_{TH} in an n-channel transistor is identified as a normally-OFF device.

For validating the erase operation, a virgin device was initially programmed to a V_{TH} of 0.3 V followed by the application of negative voltage pulses in the control gate 318. Likewise, a negative V_{TH} shift was observed after the erase operation, as observed in FIG. 5B. To validate the program/erase (P/E) repeatability, a virgin device was initially programmed followed by the erase operation. After the 1^{st} program/erase (P/E) cycle, the device was tested for a 2nd P/E cycle, as highlighted in FIG. 5C. Note that the virgin device and the device after 1^{st} P/E cycle showed different sub-threshold slopes (SS). This can be attributed to the interface properties which are highly dependent on electron trapping/de-trapping phenomena, thereby influencing the SS after the 1st P/E cycle. Nevertheless, a reasonable P/E cycle repeatability after the 1st P/E cycle confirms the working β-Ga₂O₃ flash memory cell.

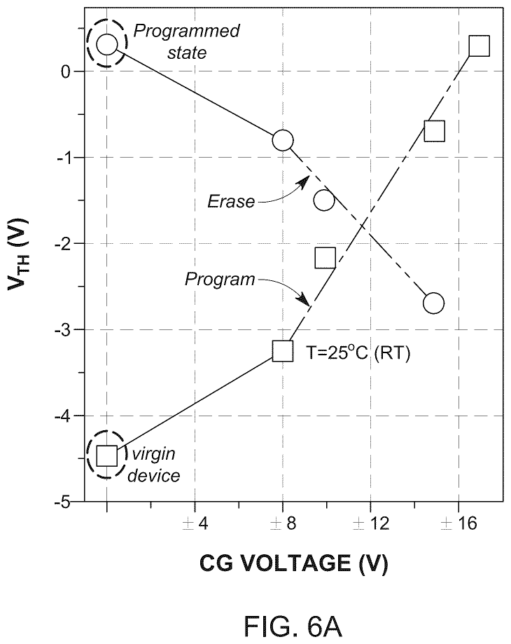

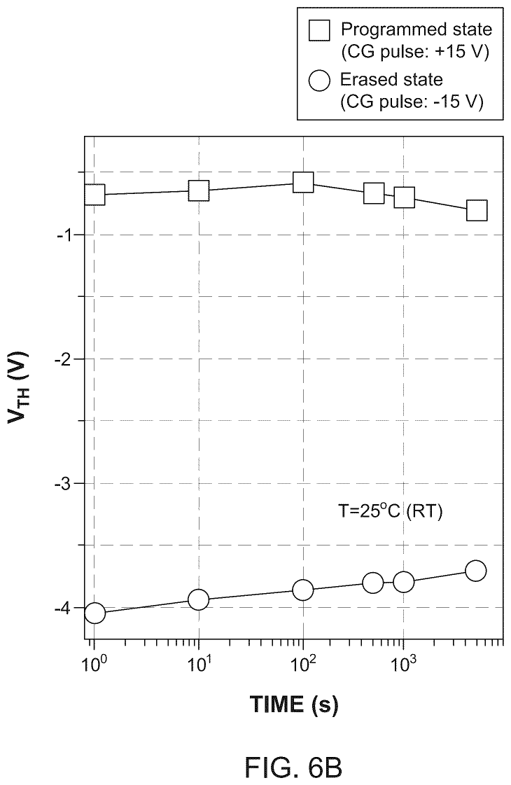

The dependence of the V_{TH} shift on the program/erase bias voltage is shown in FIG. 6A. A nonvolatile memory window of greater than 4 V is achieved by applying program/erase pulses of less than 20 V in magnitude. Once programmed or erased, an insignificant V_{TH} shift was observed even after 5000 s, as shown in FIG. 6B. Thus, the β-Ga₂O₃ flash memory cell 300 showed excellent charge retention characteristics in its nonvolatile memory states. Notably, the increase in V_{TH} during the program operation was observed to be higher than that during the erase operation (see FIG. 6A). For example, a CG pulse of +15 V during the program operation induced an effective V_{TH} shift (ΔV_{TH}) of about 4 V from the virgin state, whereas a control gate bias of −15 V during the erase operation induced an effective ΔV_{TH} of about 3 V from the programmed state. The inventors believe that a lower V_{TH} shift in β-Ga₂O₃ flash memory cells during the erase operation was likely caused by the electric field distribution inside the films and carrier tunneling paths.

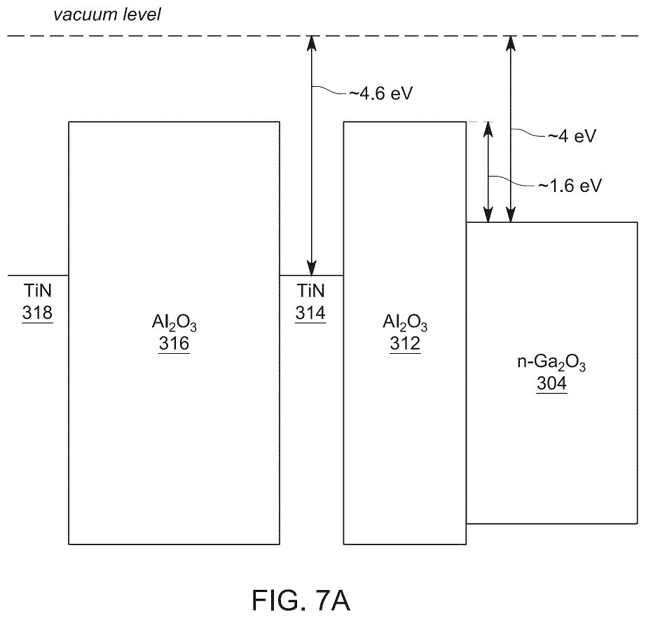

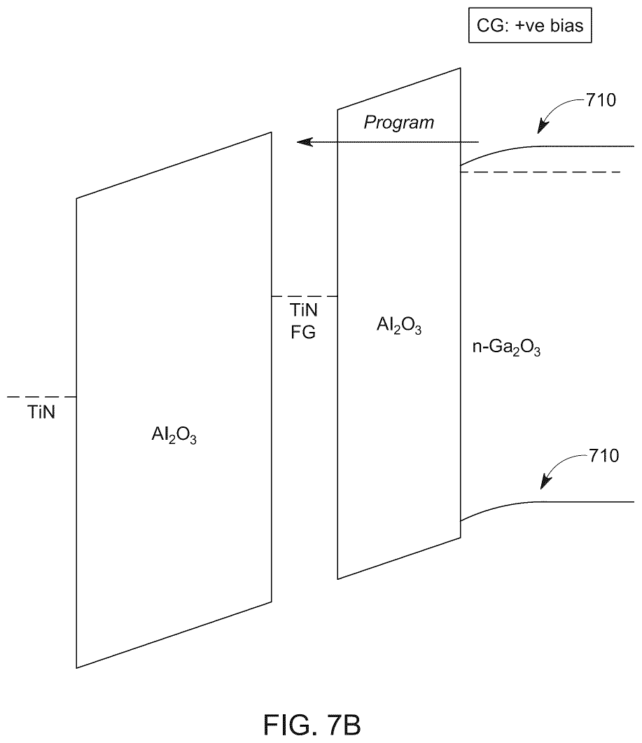

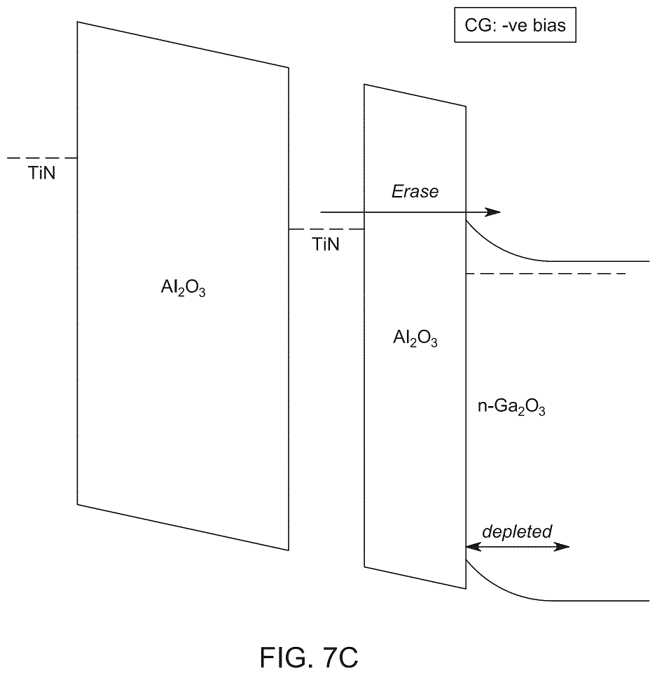

The energy band profiles of the layers of the β-Ga₂O₃ flash memory cell 300, in isolation (noncontact), during the program operation, and during the erase operation are shown in FIGS. 7A to 7C, respectively. The work function and band energy details of TiN, β-Ga₂O₃, and Al₂O₃ can be found in literature. During the program operation (arrow in the figure indicates the tunneling electrons motion direction), which is illustrated in FIG. 7B, the β-Ga₂O₃ channel is under accumulation. Since the Fermi energy level is close to the conduction band in n-type ultrawide bandgap semiconductors such as β-Ga₂O₃, the program voltage pulse applied to the control gate effectively caused a band-bending 710 across the tunneling and blocking oxides, as highlighted in FIG. 7B. However, the device V_{TH} was nearly positive at the programmed state. Thus, a relatively larger area of β-Ga₂O₃ film 304 under the gate 310 is fully depleted when electrons are stored in the FG 314 after the program operation. Therefore, a portion of the erase voltage pulse applied to the control gate was sustained by the depleted β-Ga₂O₃ film 304 along with the tunneling and blocking oxides, as highlighted in FIG. 7C.

Moreover, to obtain a similar V_{TH} shift, the desired erase pulse duration was observed to be significantly higher than the program pulse duration (not shown). All of these observations exhibited good agreement with the conventional FG 314 or charge-trap NAND flash memories realized on Si. Note that the device |V_{TH}| after the erase operation was observed to be lower than |V_{TH}| of the virgin device indicating the erase operation was unable to remove all the electrons injected into the FG 314 during the program operation. Moreover, improving the erase characteristics by hole injection into the FG 314 is an unlikely case for β-Ga₂O₃ flash memory cells. Traditionally, planar Si flash memories are fabricated on a p-type substrate, whereas 3D-NAND flash memories are fabricated on poly-Si pillars. During the erase operation, holes can be injected from the channel to the charge-trap layer, which is between the tunneling oxide and gate oxide layers. Therefore, the choice of proper hole charge-trap dielectric has been observed to improve the erase characteristics of both planar and 3D Si flash memories. In contrast, a low intrinsic carrier concentration in β-Ga₂O₃ indicates the channel is free from holes during the erase operation. Moreover, obtaining a p-type β-Ga₂O₃ film is also a major challenge. Thus, program and erase operation in β-Ga₂O₃ flash memory cells are thought to be solely due to electron injection and removal from the FG 314.

The embodiments illustrated in the figures with regard to memory cell 300 were discussed with regard to data storage capabilities. However, the structure of the memory cell 300 may be advantageous from other points of view. For example, as observed in FIG. 6A, a program bias voltage pulse of ≥17 V results in a normally-OFF transistor (V_{TH}>0 V). Therefore, a programmed β-Ga₂O₃ flash memory cell can be used to realize standalone normally-OFF low-voltage transistors. Moreover, both high-voltage and low-voltage power switches are controlled by logic circuitry such as pulse width modulators. Traditionally, Si-based CMOS technology is used to realize this logic control circuitry. However, β-Ga₂O₃ based all-oxide electronics mandates these circuits to be realized on a native substrate. Unfortunately, the non-availability of appropriate p-type doping in β-Ga₂O₃ poses a major hindrance in realizing CMOS logic operations. Interestingly, many of these logic control circuitries can be realized using a combination of normally-ON and normally-OFF transistors. Thus, the logic circuitry for controlling the β-Ga₂O₃ power converters can be realized using a suitable connection of virgin/erased (normally-ON) β-Ga₂O₃ flash memory cell with a programmed (normally-OFF) β-Ga₂O₃ flash memory cell. Consequently, the power converters and their logic control circuitry can be monolithically integrated into a standalone β-Ga₂O₃ substrate.

Also, the flash memory cells 300 were fabricated on a foreign substrate 302 indicating the compatibility of the β-Ga₂O₃ flash memory cells with low-cost heterogeneous integration schemes. Note that the cells discussed in the above embodiments were free from the post-deposition annealing (PDA) step. However, PDA has been observed to minimize the trap density at the Al₂O₃/β-Ga₂O₃ interface, thereby improving the overall interface quality. Therefore, a more realistic β-Ga₂O₃ flash memory cell processing may require a PDA step to obtain a good tunnel oxide interface.

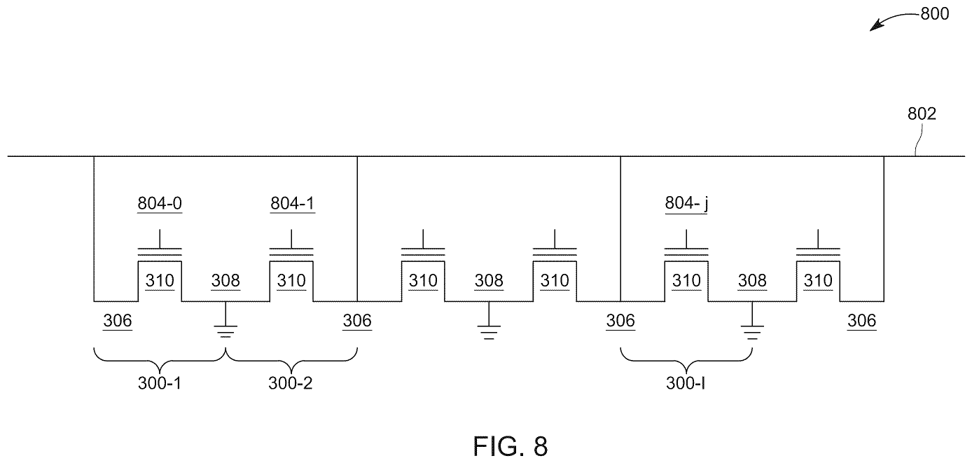

FIG. 8 illustrates a non-volatile flash memory 800 including plural memory cells 300. For simplicity, the figure shows a single bit line 802 and plural word lines 804-J, where J is an integer. Also, the figure shows a single row of memory cells 300-I, with I being an integer. However, an actual non-volatile flash memory 800 includes plural bit lines 802, and a large number of memory cells 300-I distributed along many rows and columns. FIG. 8 schematically illustrates how each memory cell 300 is wired to be programmed/erased.

The above embodiments introduced a β-Ga₂O₃ flash memory cell 300 using a TiN metal FG. A large nonvolatile memory window of >4 V was observed between the programmed and erased states. The memory cell exhibited an insignificant threshold voltage shift in the programmed and erased states even after 5000 s. The realization of enhancement-mode operation by storing electrons in the FG is thought to be advantageous for realizing multiple essential devices of β-Ga₂O₃ electronics.

The term “about” is used in this application to mean a variation of up to 20% of the parameter characterized by this term.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide a Ga₂O₃ nonvolatile flash memory for oxide electronics. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] A. J. Green et al., APL Mater. 10, 029201 (2022).
[2] S. J. Pearton, J. Yang, P. H. Cary IV, F. Ren, J. Kim, M. J. Tadjer, and M. A. Mastro, Appl. Phys. Rev. 5, 011301 (2018).
[3] A. Jadhav, L. A. M. Lyle, Z. Xu, K. K. Das, L. M. Porter, and B. Sarkar, J. Vac. Sci. Technol. B 39, 040601 (2021).
[4] X. Chen, F.-F. Ren, J. Ye, and S. Gu, Semicond. Sci. Technol. 35, 023001 (2020).
[5] W. Li, J. Wan, Z. Tu, H. Li, H. Wu, and C. Liu, Ceram. Int. 48, 3185 (2022).
[6] C.-C. Yang, J.-Q. Huang, K.-Y. Chen, P.-H. Chiu, H.-T. Vu, and Y.-K. Su, IEEE Access 7, 175186 (2019).
[7] J. Zhou, K.-H. Kim, and W. Lu, IEEE Trans. Electron Devices 61, 1369 (2014).
[8] S. Kim, J. Zhou, and W. D. Lu, IEEE Trans. Electron Devices 61, 2820 (2014).

1. A nonvolatile flash memory cell comprising:
a source electrode;
a drain electrode; and
a gate column,
wherein the drain electrode is cylindrical, the gate column is tubular and surrounds the drain electrode, and the source electrode surrounds the gate column.

2. The nonvolatile flash memory cell of claim 1, wherein each layer of the gate column is made of a metallic material or an oxide.

3. The nonvolatile flash memory cell of claim 2, wherein the oxide has a higher conduction band offset than Ga₂O₃.

4. The nonvolatile flash memory cell of claim 2, wherein the metallic material includes TiN.

5. The nonvolatile flash memory cell of claim 1, wherein
the gate column, the source electrode and the drain electrode are directly located on a β-Ga₂O₃ semiconductor film.

6. The nonvolatile flash memory cell of claim 5, wherein the gate column comprises:
a tunneling oxide layer located on the β-Ga₂O₃ semiconductor film;
a metallic floating gate located on the tunneling oxide layer; and
a blocking oxide layer located on the metallic floating gate.

7. The nonvolatile flash memory cell of claim 6, wherein the tunneling oxide layer is thinner than the blocking oxide layer.

8. The nonvolatile flash memory cell of claim 7, wherein the tunneling oxide layer and the blocking oxide layer are made of the same material.

9. The nonvolatile flash memory cell of claim 8, wherein the material is an oxide having a higher conduction band offset than Ga₂O₃.

10. The nonvolatile flash memory cell of claim 1, wherein the source electrode is tubular.

11. A nonvolatile flash memory comprising:
plural nonvolatile flash memory cells;
plural bit lines connected to source electrodes of the plural memory cells; and
plural word lines connected to gate electrodes of the plural memory cells,
wherein a memory cell of the plural memory cells comprises,
a source electrode;
a drain electrode; and
a gate column,
wherein the drain electrode is cylindrical, the gate column is tubular and surrounds the drain electrode, and the source electrode surrounds the gate column.

12. The nonvolatile flash memory of claim 11, wherein each layer of the gate column is made of a metallic material or an oxide.

13. The nonvolatile flash memory of claim 12, wherein the oxide has a higher conduction band offset than Ga₂O₃.

14. The nonvolatile flash memory of claim 12, wherein the metallic material includes TiN.

15. The nonvolatile flash memory of claim 11, wherein the gate column, the source electrode and the drain electrode are directly located on a β-Ga₂O₃ semiconductor film.

16. The nonvolatile flash memory of claim 15, wherein the gate column comprises:
a tunneling oxide layer located on the β-Ga₂O₃ semiconductor film;
a metallic floating gate located on the tunneling oxide layer; and
a blocking oxide layer located on the metallic floating gate.

17. The nonvolatile flash memory of claim 16, wherein the tunneling oxide layer is thinner than the blocking oxide layer.

18. The nonvolatile flash memory of claim 17, wherein the tunneling oxide layer and the blocking oxide layer are made of the same material.

19. The nonvolatile flash memory of claim 18, wherein the material is an oxide having a higher conduction band offset than Ga₂O₃.

20. The nonvolatile flash memory of claim 11, wherein the source electrode is tubular.
